(19) United States
(12) Patent Application Publication
(10) Pub. No.: US 2026/0180586 A1
(43) Pub. Date: Jun. 25, 2026

(54) CALIBRATION CIRCUIT

(71) Applicant: SONY SEMICONDUCTOR SOLUTIONS CORPORATION, KANAGAWA (JP)

(72) Inventor: HIDEYUKI TAKANO, KANAGAWA (JP)

(21) Appl. No.: 18/726,549

(22) PCT Filed: Jan. 6, 2022
(86) PCT No.: PCT/JP2022/042342

§ 371 Date: Jul. 3, 2024

(30) Foreign Application Priority Data
Jan. 12, 2022 (JP) 2022-003131

(51) Int. Cl. H03L 7/099; H03B 5/12; H03L 7/085; H03L 7/18; H03L 7/183

(52) U.S. Cl. CPC H03L 7/099; H03B 5/1243; H03L 7/085; H03L 7/18; H03L 7/183

(57) ABSTRACT

To suppress an increase in power consumption during steady operation while preventing oscillation from stopping during the calibration of an LC oscillator. A calibration circuit includes a reference voltage generation unit, a voltage comparison unit, and an amplitude adjustment unit. The reference voltage generation unit generates a plurality of different reference voltages. The voltage comparison unit compares a detection value of an oscillation amplitude detected from an oscillation signal of the LC oscillator and the plurality of different reference voltages on the same polarity side of the oscillation amplitude. The amplitude adjustment unit adjusts the oscillation amplitude on the basis of a comparison result by the voltage comparison unit. The calibration circuit may include a frequency adjustment unit that adjusts an oscillation frequency of the LC oscillator.

### TECHNICAL FIELD

The present technology relates to a calibration circuit. Specifically, the present technology relates to a calibration circuit for an LC oscillator.

### BACKGROUND ART

An LC oscillator may be used in order to generate a clock. Since the oscillation frequency and the oscillation amplitude of the LC oscillator fluctuate under the influence of temperature, power supply voltage, element variation, and the like, calibration may be performed at the time of activation. For example, there has been a proposal to detect a maximum value and a minimum value of oscillation output and output a control voltage for changing a bias current of a voltage-controlled oscillation circuit to make a difference between these values equal to a reference voltage (for example, Patent Document 1).

### CITATION LIST

### Patent Document

Patent Document 1: Japanese Patent Application Laid-Open No. 2006-197571

### SUMMARY OF THE INVENTION

### Problems to be Solved by the Invention

The oscillation amplitude of the LC oscillator increases or decreases in proportion to the oscillation frequency. Therefore, in the above-described conventional technique, oscillation may stop during frequency calibration if frequency calibration is performed subsequently to amplitude calibration of the LC oscillator. On the other hand, if the reference voltage for setting the difference between the maximum value and the minimum value of the oscillation output is increased in order to prevent oscillation from stopping during frequency calibration, the oscillation amplitude of the LC oscillator increases, which may lead to an increase in power consumption and phase noise during steady operation.

The present technology has been made in view of such a situation, and an object of the present technology is to suppress an increase in power consumption during steady operation while preventing oscillation from stopping during calibration of the LC oscillator.

### Solutions to Problems

The present technology has been made to solve the above-described problems, and a first aspect thereof is a calibration circuit including a reference voltage generation unit that generates a plurality of different reference voltages, a voltage comparison unit that compares a detection value of an oscillation amplitude detected from an oscillation signal of an LC oscillator and the plurality of different reference voltages on the same polarity side of the oscillation amplitude, and an amplitude adjustment unit that adjusts the oscillation amplitude on the basis of a comparison result by the voltage comparison unit. This brings about the effect of gradually adjusting the oscillation amplitude of the LC oscillator.

In addition, in the first aspect, the same polarity side of the oscillation amplitude may be a positive electrode side or a negative electrode side of the oscillation amplitude. This brings about the effect of comparing the detection value of the oscillation amplitude detected from the oscillation signal of the LC oscillator and the plurality of different reference voltages on the same polarity side of the oscillation amplitude.

Furthermore, the first aspect may further include a frequency adjustment unit that adjusts an oscillation frequency of the LC oscillator. This brings about the effect of adjusting the oscillation frequency while gradually adjusting the oscillation amplitude of the LC oscillator.

Moreover, the first aspect may further include a detection circuit that detects the detection value on the same polarity side of the oscillation amplitude of the LC oscillator on the basis of detection of the oscillation signal of the LC oscillator. This brings about the effect of detecting the detection value of the oscillation amplitude, which is to be compared with the plurality of different reference voltages on the same polarity of the oscillation amplitude, from the oscillation signal of the LC oscillator.

Furthermore, according to the first aspect, the detection circuit may include a full-wave rectifier circuit that subjects the oscillation signal of the LC oscillator to full-wave rectification, and a smoothing circuit that smooths a waveform subjected to full-wave rectification by the full-wave rectifier circuit. This brings about the effect of setting the value on the same polarity side of the oscillation amplitude, which is to be compared with the plurality of different reference voltages.

Moreover, according to the first aspect, the reference voltages may include a first reference voltage, a second reference voltage greater than the first reference voltage, and a third reference voltage greater than the second reference voltage. The amplitude adjustment unit may be configured to adjust the oscillation amplitude to make the detection value of the oscillation amplitude greater than or equal to the third reference voltage on the same polarity side of the oscillation amplitude in a first amplitude calibration period. The frequency adjustment unit may be configured to adjust the oscillation frequency to make a frequency error of the LC oscillator less than or equal to an allowable value in a frequency calibration period after the first amplitude calibration period. The amplitude adjustment unit may be configured to adjust the oscillation amplitude to make the detection value of the oscillation amplitude greater than or equal to the first reference voltage but less than the second reference voltage on the same polarity side of the oscillation amplitude in a second amplitude calibration period after the frequency calibration period. This brings about the effect of making the oscillation amplitude during the steady operation of the LC oscillator smaller than the oscillation amplitude in the frequency calibration period.

Furthermore, the first aspect may further include a state management unit that manages the first amplitude calibration period, the frequency calibration period, and the second amplitude calibration period. This brings about the effect of setting the frequency calibration period between the first amplitude calibration period and the second amplitude calibration period.

### BRIEF DESCRIPTION OF DRAWINGS

FIG. 1 is a diagram illustrating a configuration example of a calibration circuit according to a first embodiment.

FIG. 2 is a diagram illustrating an example of the value of comparator output according to the first embodiment.

FIG. 3 is a timing chart illustrating an example of a calibration operation according to the first embodiment.

FIG. 4 is a flowchart illustrating an example of a first amplitude calibration operation according to the first embodiment.

FIG. 5 is a flowchart illustrating an example of a frequency calibration operation according to the first embodiment.

FIG. 6 is a flowchart illustrating an example of a second amplitude calibration operation according to the first embodiment.

FIG. 7 is a diagram illustrating a configuration example of a calibration circuit according to a second embodiment.

### MODE FOR CARRYING OUT THE INVENTION

Modes for carrying out the present technology (hereinafter, referred to as embodiments) will be described hereinafter. The description will be given in the following order.
1. First embodiment (configuration example in which a detection value of an oscillation amplitude is compared with three different reference voltages on the positive electrode side of the oscillation amplitude of an LC oscillator, and calibration is performed on the basis of the comparison result)
2. Second embodiment (example in which a detection circuit and a voltage comparison unit of a calibration circuit include field effect transistors)

### 1. First Embodiment

In the first embodiment, a detection value Vdet of an oscillation amplitude Vosc detected from an oscillation signal Vsd of an LC oscillator 100 and reference voltages Vref1 to Vref3 are compared on the same polarity side of the oscillation amplitude Vosc. In the first embodiment, a case where the same polarity side of the oscillation amplitude Vosc is the positive electrode side of the oscillation amplitude Vosc is taken as an example.

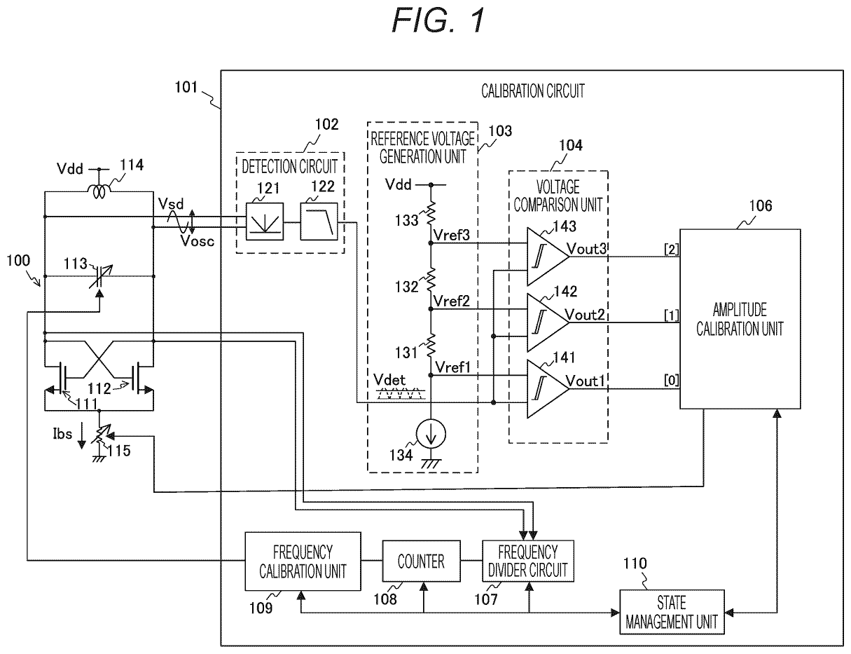

FIG. 1 is a diagram illustrating a configuration example of a calibration circuit according to the first embodiment.

In the figure, the LC oscillator 100 generates an oscillation signal Vsd on the basis of the resonance between a capacitor bank 113 and an inductor 114. The oscillation signal Vsd is a differential output signal. The LC oscillator 100 includes transistors 111 and 112, the capacitor bank 113, the inductor 114, and a variable resistor 115. The transistors 111 and 112 are N-channel field effect transistors. The capacitor bank 113 can switch the capacitance value on the basis of a command from a frequency calibration unit 109. The variable resistor 115 can change the resistance value on the basis of a command from an amplitude calibration unit 106.

The capacitor bank 113 and the inductor 114 are connected in parallel to each other. The respective drains of the transistors 111 and 112 are connected to both ends of the capacitor bank 113. In addition, the drain of the transistor 111 is connected to the gate of the transistor 112, and the drain of the transistor 112 is connected to the gate of the transistor 111. The respective sources of the transistors 111 and 112 are connected to a ground potential via the variable resistor 115. A center tap of the inductor 114 is connected to a power supply potential Vdd.

The calibration circuit 101 includes a detection circuit 102, a reference voltage generation unit 103, and a voltage comparison unit 104. In addition, the calibration circuit 101 includes the amplitude calibration unit 106, a frequency divider circuit 107, a counter 108, the frequency calibration unit 109, and a state management unit 110.

The detection circuit 102 detects a detection value Vdet on the positive electrode side of the oscillation amplitude Vosc of the LC oscillator 100 on the basis of detection of an oscillation signal Vsd of the LC oscillator 100. The detection circuit 102 includes a full-wave rectifier circuit 121 and a smoothing circuit 122. The full-wave rectifier circuit 121 subjects the oscillation signal Vsd of the LC oscillator 100 to full-wave rectification. The smoothing circuit 122 generates the detection value Vdet on the positive electrode side of the oscillation amplitude Vosc by smoothing the waveform subjected to full-wave rectification by the full-wave rectifier circuit 121. Note that the detection value Vdet on the positive electrode side of the oscillation amplitude Vosc is an average value obtained by averaging instantaneous values on the positive electrode side of the oscillation amplitude Vosc over a certain period.

The reference voltage generation unit 103 generates the three different reference voltages Vref1 to Vref3. At this time, the reference voltages Vref1 to Vref3 can have the relationship of Vref1<Vref2<Vref3. The reference voltage generation unit 103 includes resistors 131 to 133 and a current source 134. The resistors 131 to 133 are connected in series to each other, the other end of the resistor 133 is connected to the power supply potential Vdd, and the other end of the resistor 131 is connected to the ground potential via the current source 134.

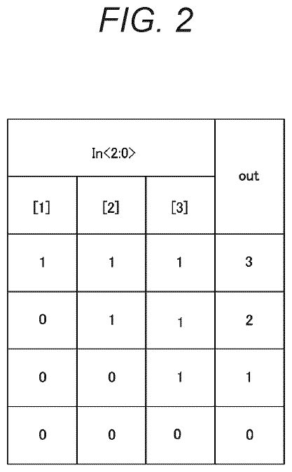

The voltage comparison unit 104 compares the detection value Vdet of the oscillation amplitude Vosc detected from the oscillation signal Vsd of the LC oscillator 100 with the reference voltages Vref1 to Vref3 on the positive electrode side of the oscillation amplitude Vosc. The voltage comparison unit 104 includes comparators 141 to 143. The comparator 141 compares the detection value Vdet on the positive electrode side of the oscillation amplitude Vosc detected by the detection circuit 102 with the reference voltage Vref1. The comparator 142 compares the detection value Vdet on the positive electrode side of the oscillation amplitude Vosc detected by the detection circuit 102 with the reference voltage Vref2. The comparator 143 compares the detection value Vdet on the positive electrode side of the oscillation amplitude Vosc detected by the detection circuit 102 with the reference voltage Vref3. At this time, the respective output voltages Vout1 to Vout3 of the comparators 141 to 143 take logic levels of ‘0’ or ‘1’. Then, as illustrated in FIG. 2, input In<2:0> of [0] to [2] respectively corresponding to the logic levels of the output voltages Vout1 to Vout3 are input to the amplitude calibration unit 106 as comparator output out. Note that in the figure, the value of the comparator output out when the input In<2:0> is ‘111’ is set to 3, and the value of the comparator output out when the input In<2:0> is ‘011’ is set to 2. In addition, the value of the comparator output out when the input In<2:0> is ‘001’ is set to 1, and the value of the comparator output out when the input In<2:0> is ‘000’ is set to 0.

The amplitude calibration unit 106 adjusts the oscillation amplitude Vosc of the LC oscillator 100 on the basis of the comparison result by the voltage comparison unit 104. For example, the amplitude calibration unit 106 can adjust the oscillation amplitude Vosc to make the detection value Vdet on the positive electrode side of the oscillation amplitude Vosc of the LC oscillator 100 greater than or equal to the reference voltage Vref3, before frequency calibration. Furthermore, the amplitude calibration unit 106 can adjust the oscillation amplitude Vosc to make the detection value Vdet on the positive electrode side of the oscillation amplitude Vosc of the LC oscillator 100 greater than or equal to the reference voltage Vref1 but less than the reference voltage Vref2, after frequency calibration. Note that the amplitude calibration unit 106 is an example of an amplitude adjustment unit recited in the claims.

The amplitude calibration unit 106 can adjust the resistance value of the variable resistor 115 in order to adjust the oscillation amplitude Vosc of the LC oscillator 100. At this time, the bias current Ibc of the LC oscillator 100 changes according to the resistance value of the variable resistor 115, and the oscillation amplitude Vosc of the LC oscillator 100 changes.

The frequency divider circuit 107 divides the frequency of the oscillation signal Vsd of the LC oscillator 100. The counter 108 outputs a count value corresponding to the frequency of the oscillation signal Vsd of the LC oscillator 100 on the basis of the output of the frequency divider circuit 107.

The frequency calibration unit 109 adjusts the oscillation frequency fosc of the LC oscillator 100. For example, the frequency calibration unit 109 can adjust the oscillation frequency fosc to make the frequency error of the LC oscillator 100 less than or equal to an allowable value. At this time, the frequency calibration unit 109 can switch the capacitance value of the capacitor bank 113 in order to adjust the oscillation frequency fosc of the LC oscillator 100. Note that the frequency calibration unit 109 is an example of a frequency adjustment unit recited in the claims.

The state management unit 110 manages an amplitude calibration period of the amplitude calibration unit 106 and a frequency calibration period of the frequency calibration unit 109. At this time, the state management unit 110 can shift to the frequency calibration period after the detection value Vdet on the positive electrode side of the oscillation amplitude Vosc of the LC oscillator 100 is adjusted to be greater than or equal to the reference voltage Vref3 in the amplitude calibration period. In addition, the state management unit 110 can shift to the amplitude calibration period again after the frequency calibration period and adjust the detection value Vdet on the positive electrode side of the oscillation amplitude Vosc of the LC oscillator 100 to make it greater than or equal to the reference voltage Vref1 but less than the reference voltage Vref2.

Note that the state management unit 110 may be realized by reading a program related to the state management of the calibration circuit 101 from a memory and causing a processor such as a central processing unit (CPU) to execute the program. Alternatively, the state management unit 110 may be realized by hardware such as a logic circuit.

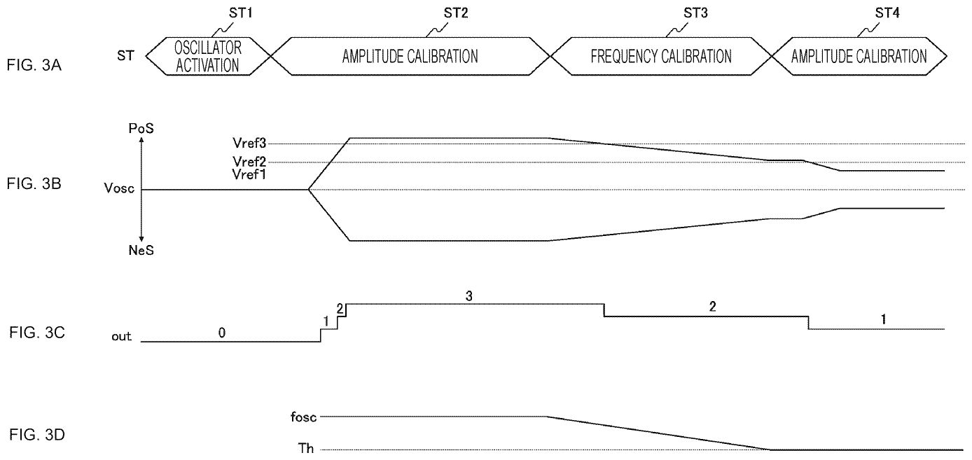

FIG. 3 is a timing chart illustrating an example of a calibration operation according to the first embodiment. Note that a in the figure illustrates a state ST of the calibration circuit 101. In the figure, b illustrates changes in the oscillation amplitude Vosc according to the state ST of the calibration circuit 101. In the figure, c illustrates the value of the comparator output out according to the state ST of the calibration circuit 101. In the figure, d illustrates the oscillation frequency fosc of the oscillation signal Vsd according to the state ST of the calibration circuit 101.

In a of the figure, the state management unit 110 manages an oscillator activation period ST1, an amplitude calibration period ST2, a frequency calibration period ST3, and an amplitude calibration period ST4 as the state ST of the calibration circuit 101.

In the oscillator activation period ST1, the LC oscillator 100 is activated. At this time, the voltage across the parallel circuit of the capacitor bank 113 and the inductor 114 is applied to the respective gates of the transistors 111 and 112 as differential input, and differentiated oscillation signals Vsd are output from the respective drains of the transistors 111 and 112 to the detection circuit 102. At this time, the oscillation signals Vsd alternately repeat a waveform on the positive electrode side and a waveform on the negative electrode side. Here, the positive electrode side of the oscillation amplitude Vosc is indicated by PoS, and the negative electrode side of the oscillation amplitude Vosc is indicated by NeS, as illustrated in b of the figure.

In the detection circuit 102, the detection value Vdet on the positive electrode side PoS of the oscillation amplitude Vosc is detected from the oscillation signals Vsd output from the LC oscillator 100, and input to each of the comparators 141 to 143. Furthermore, in the reference voltage generation unit 103, a current generated by the current source 134 flows through the resistors 131 to 133, and the reference voltages Vref1 to Vref3 are thereby generated on the basis of the voltage drop of each of the resistors 131 to 133 and input to each of the comparators 141 to 143.

Each of the comparators 141 to 143 compares the detection value Vdet on the positive electrode side PoS of the oscillation amplitude Vosc with the reference voltages Vref1 to Vref3, respectively. Then, the respective output voltages Vout1 to Vout3 of the comparators 141 to 143 are input to the amplitude calibration unit 106 as the comparator output out.

Next, when the oscillator activation period ST1 ends, the state management unit 110 shifts to the amplitude calibration period ST2 and activates the amplitude calibration unit 106. Then, the amplitude calibration unit 106 adjusts the oscillation amplitude Vosc of the LC oscillator 100 to make the comparator output out greater than or equal to 3, as illustrated in b and c of the figure. At this time, if the comparator output out is greater than or equal to 3, the detection value Vdet on the positive electrode side PoS of the oscillation amplitude Vosc is greater than or equal to the reference voltage Vref3.

Next, when the amplitude calibration period ST2 ends, the state management unit 110 shifts to the frequency calibration period ST3 and activates the frequency divider circuit 107, the counter 108, and the frequency calibration unit 109. At this time, after the frequency divider circuit 107 divides the frequency of the oscillation signal Vsd of the LC oscillator 100, the counter 108 generates the count value corresponding to the frequency of the oscillation signals Vsd of the LC oscillator 100 and inputs it to the frequency calibration unit 109. Then, the frequency calibration unit 109 adjusts the oscillation frequency fosc of the LC oscillator 100 to make it equal to a target value Th, as illustrated in d of the figure.

Here, the relationship between the oscillation amplitude Vosc and the oscillation frequency fosc of the LC oscillator 100 can be calculated as follows. Assuming that the LC oscillator 100 operates in class B, a fundamental wave component Itk of the current flowing through the capacitor bank 113 and the inductor 114 during the oscillation of the LC oscillator 100 can be given by the following equation.

$$Itk = 2 / π \cdot Ibs$$

In addition, resonance impedance Rtk by the capacitor bank 113 and the inductor 114 at the oscillation frequency fosc can be given by the following equation.

$$Rtk = ω LQ = 2 π fosc \cdot LQ$$

In the equation, Q is the Q value of the inductor 114.

Thus, the oscillation amplitude Vosc can be given by the following equation.

$$Vosc = 2 Itk \cdot Rtk = 8 Ibs \cdot fosc \cdot LQ$$

According to the above equation, the oscillation amplitude Vosc increases or decreases in proportion to the oscillation frequency fosc. Therefore, the oscillation amplitude Vosc decreases as the oscillation frequency fosc decreases, and if the oscillation frequency fosc becomes too small, the oscillation of the LC oscillator 100 stops. For this reason, the reference voltage generation unit 103 can set the reference voltage Vref3 to prevent the oscillation of the LC oscillator 100 from stopping in the frequency calibration period ST3.

Next, when the frequency calibration period ST3 ends, the state management unit 110 shifts to the amplitude calibration period ST4 and activates the amplitude calibration unit 106 again. Then, the amplitude calibration unit 106 adjusts the oscillation amplitude Vosc of the LC oscillator 100 to make the comparator output out greater than or equal to 1 but less than 2, as illustrated in b and c of the figure. At this time, if the comparator output out is greater than or equal to 1 but less than 2, the detection value Vdet on the positive electrode side PoS of the oscillation amplitude Vosc is greater than or equal to the reference voltage Vref1 but less than the reference voltage Vref2.

After the detection value Vdet on the positive electrode side PoS of the oscillation amplitude Vosc is set to be greater than or equal to the reference voltage Vref1 but less than the reference voltage Vref2, the LC oscillator 100 shifts to the steady operation. At this time, the reference voltage Vref1 of the LC oscillator 100 can be set to allow stable operation during the steady operation of the LC oscillator 100. In addition, it is preferable that the reference voltage Vref2 be as small as possible, in order to suppress the current consumption of the LC oscillator 100. At this time, the reference voltage Vref2 may be made equal to the reference voltage Vref1. However, increasing the reference voltage Vref2 can shorten the time for the detection value Vdet on the positive electrode side PoS of the oscillation amplitude Vosc to become greater than or equal to the reference voltage Vref1 but less than the reference voltage Vref2, and can shorten the amplitude calibration period ST4.

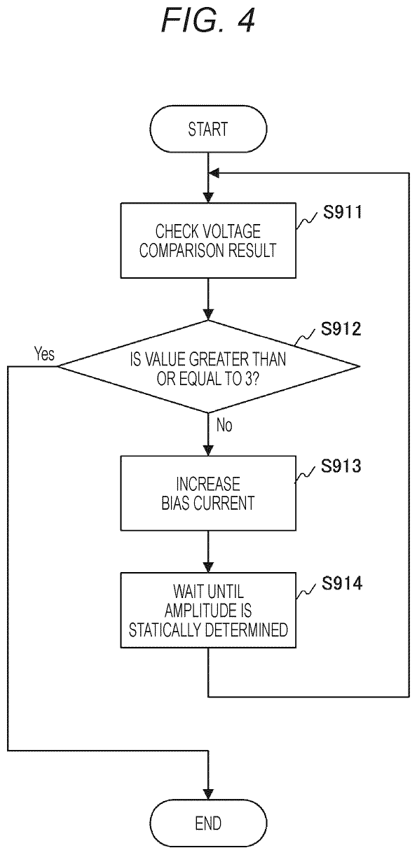

FIG. 4 is a flowchart illustrating an example of a first amplitude calibration operation according to the first embodiment.

In the figure, when the amplitude calibration is activated, the amplitude calibration unit 106 checks the comparator output out (step S911).

Next, the amplitude calibration unit 106 determines whether or not the comparator output out is greater than or equal to 3 (step S912). In a case where the comparator output out is greater than or equal to 3 (Yes in step S912), the amplitude calibration unit 106 ends the amplitude calibration. In contrast, in a case where the comparator output out is not greater than or equal to 3 (No in step S912), the amplitude calibration unit 106 adjusts the resistance value of the variable resistor 115 and changes the bias current Ibc of the LC oscillator 100 (step S913).

Next, the amplitude calibration unit 106 waits until the oscillation amplitude Vosc of the LC oscillator 100 is statically determined (step S914), and then returns to the processing of step S911.

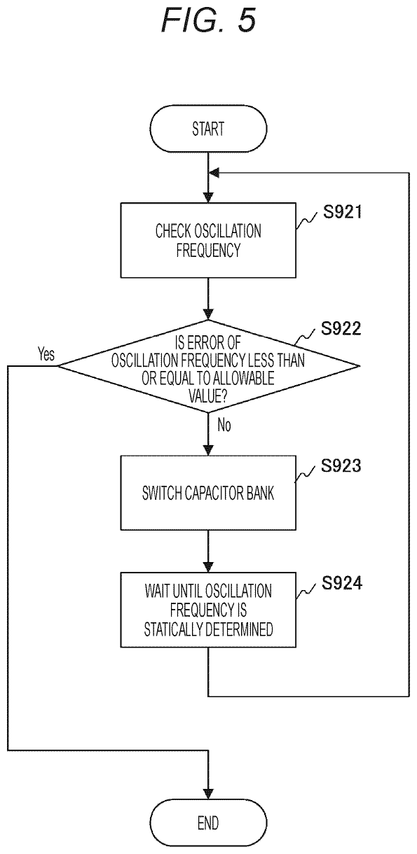

FIG. 5 is a flowchart illustrating an example of a frequency calibration operation according to the first embodiment.

In the figure, when the frequency calibration is activated, the frequency calibration unit 109 checks the oscillation frequency fosc of the LC oscillator 100 (step S921).

Next, the frequency calibration unit 109 determines whether or not the error of the oscillation frequency fosc of the LC oscillator 100 is less than or equal to an allowable value (step S922). In a case where the error of the oscillation frequency fosc of the LC oscillator 100 is less than or equal to the allowable value (Yes in step S922), the frequency calibration unit 109 ends the frequency calibration. In contrast, in a case where the error of the oscillation frequency fosc of the LC oscillator 100 is not less than or equal to the allowable value (No in step S922), the frequency calibration unit 109 switches the capacitance value of the capacitor bank 113 and changes the oscillation frequency fosc of the LC oscillator 100 (step S923).

Next, the frequency calibration unit 109 waits until the oscillation frequency fosc of the LC oscillator 100 is statically determined (step S924), and then returns to the processing of step S921.

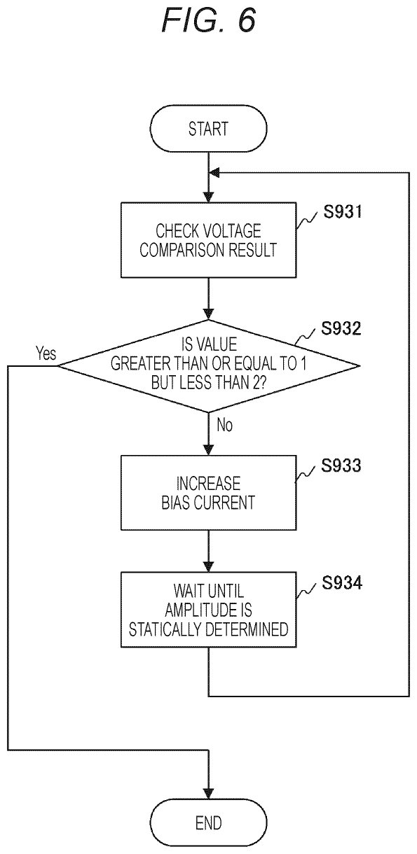

FIG. 6 is a flowchart illustrating an example of a second amplitude calibration operation according to the first embodiment.

In the figure, when the amplitude calibration is activated again, the amplitude calibration unit 106 checks the comparator output out (step S931).

Next, the amplitude calibration unit 106 determines whether or not the comparator output out is greater than or equal to 1 but less than 2 (step S932). In a case where the comparator output out is greater than or equal to 1 but less than 2 (Yes in step S932), the amplitude calibration unit 106 ends the amplitude calibration. In contrast, in a case where the comparator output out is not greater than or equal to 1 but less than 2 (No in step S932), the amplitude calibration unit 106 adjusts the resistance value of the variable resistor 115 and changes the bias current Ibc of the LC oscillator 100 (step S933).

Next, the amplitude calibration unit 106 waits until the oscillation amplitude Vosc of the LC oscillator 100 is statically determined (step S934), and then returns to the processing of step S931.

In this manner, in the first embodiment described above, the detection value Vdet on the positive electrode side Pos of the oscillation amplitude Vosc of the LC oscillator 100 is compared with the plurality of different reference voltages Vref1 to Vref3. This makes it possible to gradually adjust the oscillation amplitude Vosc of the LC oscillator 100, and to reduce the oscillation amplitude Vosc during the steady operation of the LC oscillator 100, as compared to the oscillation amplitude Vosc in the frequency calibration period ST3. As a result, it is possible to suppress an increase in power consumption during the steady operation while preventing the oscillation of the LC oscillator 100 from stopping during the frequency calibration. In addition, it is unnecessary to increase the oscillation amplitude Vosc during the steady operation to prevent the oscillation of the LC oscillator 100 from stopping during the frequency calibration, so that the phase noise of the LC oscillator 100 can be reduced.

### 2. Second Embodiment

In the first embodiment described above, the detection value Vdet of the oscillation amplitude Vosc detected from the oscillation signal Vsd of the LC oscillator 100 and the reference voltages Vref1 to Vref3 are compared on the positive electrode side Pos of the oscillation amplitude Vosc. In the second embodiment, a detection circuit 102 and a voltage comparison unit 104 of a calibration circuit 101 include field effect transistors.

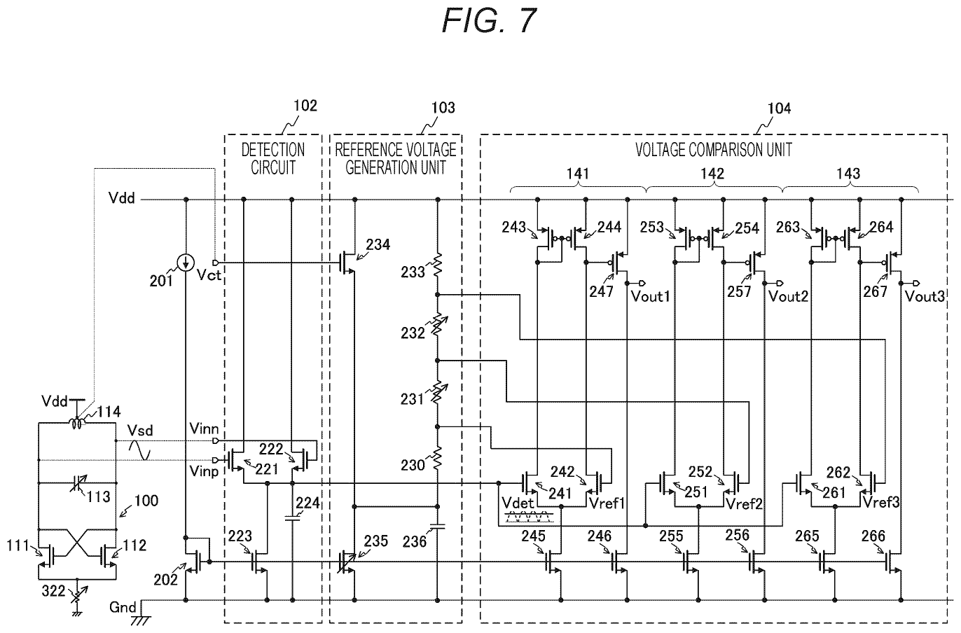

FIG. 7 is a diagram illustrating a configuration example of a calibration circuit according to the second embodiment.

In the figure, the detection circuit 102 includes transistors 221 to 223 and a capacitor 224. Each of the transistors 221 to 223 is an N-channel field effect transistor.

The respective drains of the transistors 221 and 222 are connected to a power supply potential Vdd, and the respective sources of the transistors 221 and 222 are connected to a ground potential Gnd via the transistor 223. Differentiated oscillation signals Vsd are input to the respective gates of the transistors 221 and 222 as differential input Vinp and Vinn. The capacitor 224 is connected in parallel to the transistor 223.

A reference voltage generation unit 103 includes resistors 230 to 233, transistors 224 and 235, and a capacitor 236. Each of the transistors 234 and 235 is an N-channel field effect transistor. The transistor 235 can operate as a current source 134. The transistor 235 is connected in series to the transistor 234, the drain of the transistor 234 is connected to the power supply potential Vdd, and the source of the transistor 235 is connected to the ground potential Gnd. The gate of the transistor 234 is connected to a center tap of an inductor 114. At this time, the power supply potential Vdd is applied to the gate of the transistor 234 as an input voltage Vct.

The resistors 230 to 233 are connected in series to each other, one end of the resistor 233 is connected to the power supply potential Vdd, and one end of the resistor 230 is connected to the ground potential Gnd via the transistor 235. The capacitor 236 is connected in parallel to the transistor 235.

A voltage comparison unit 104 includes transistors 241 to 247, 251 to 257, and 261 to 267. Each of the transistors 241, 242, 245, 246, 251, 252, 255, 256, 261, 262, 265, and 266 is an N-channel field effect transistor. Each of transistors 243, 244, 247, 253, 254, 257, 263, 264, and 267 is a P-channel field effect transistor.

In a comparator 141, the transistors 241 and 242 are connected in series to the transistors 243 and 244, respectively. The respective sources of the transistors 241 and 242 are connected to the ground potential Gnd via the transistor 245. The gate of the transistor 241 is connected to the source of the transistor 222, and the gate of the transistor 242 is connected to a connection point between the resistors 230 and 231. The respective gates of the transistors 243 and 244 are connected to the drain of the transistor 243. The transistor 246 is connected in series to the transistor 247. The source of the transistor 246 is connected to the ground potential Gnd. The source of the transistor 247 is connected to the power supply potential Vdd, and the gate of the transistor 247 is connected to the drain of the transistor 244. An output voltage Vout1 is output from the drain of the transistor 247.

In a comparator 142, the transistors 251 and 252 are connected in series to the transistors 253 and 254, respectively. The respective sources of the transistors 251 and 252 are connected to the ground potential Gnd via the transistor 255. The gate of the transistor 251 is connected to the source of the transistor 222, and the gate of the transistor 252 is connected to a connection point between the resistors 231 and 232. The respective gates of the transistors 253 and 254 are connected to the drain of the transistor 253. The transistor 256 is connected in series to the transistor 257. The source of the transistor 256 is connected to the ground potential Gnd. The source of the transistor 257 is connected to the power supply potential Vdd, and the gate of the transistor 257 is connected to the drain of the transistor 254. An output voltage Vout2 is output from the drain of the transistor 257.

In a comparator 143, the transistors 261 and 262 are connected in series to the transistors 263 and 264, respectively. The respective sources of the transistors 261 and 262 is connected to the ground potential Gnd via the transistor 265. The gate of the transistor 261 is connected to the source of the transistor 222, and the gate of the transistor 262 is connected to a connection point between the resistors 232 and 233. The respective gates of the transistors 263 and 264 are connected to the drain of the transistor 263. The transistor 266 is connected in series to the transistor 267. The source of the transistor 266 is connected to the ground potential Gnd. The source of the transistor 267 is connected to the power supply potential Vdd, and the gate of the transistor 267 is connected to the drain of the transistor 264. An output voltage Vout3 is output from the drain of the transistor 267.

In addition, a transistor 202 is connected between the power supply potential Vdd and the ground potential Gnd via a current source 201. The transistor 202 is an N-channel field effect transistor. The respective gates of the transistors 202, 223, 235, 245, 246, 255, 256, 265, and 266 are connected to the drain of the transistor 202. At this time, the transistors 202, 223, 235, 245, 246, 255, 256, 265, and 266 can perform a current mirror operation.

Then, in the detection circuit 102, the differentiated oscillation signals Vsd are input to the respective gates of the transistors 221 and 222 as the differential input Vinp and Vinn, and the oscillation signals Vsd are subjected to full-wave rectification on the basis of the differential operation of the transistors 221 and 222. Then, the waveform which has been subjected to full-wave rectification is smoothed by the capacitor 236, so that a detection value Vdet on the positive electrode side of an oscillation amplitude Vosc is detected and applied to the respective gates of the transistors 241, 251, and 261.

Furthermore, in the reference voltage generation unit 103, a current generated by the transistor 235 flows through the resistors 230 to 233, so that reference voltages Vref1 to Vref3 are generated and applied to the respective gates of the transistors 242, 252, and 262.

Here, assuming that the resistance values of the resistors 230 to 233 are R0 to R3, respectively, the reference voltages Vref1 to Vref3 can be given by the following equations.

$$Vref 1 = Vdd - ( R 1 + R 2 + R 3 ) \cdot Vgs / ( R 0 + R 1 + R 2 + R 3 )$$

$$Vref 2 = Vdd - ( R 2 + R 3 ) \cdot Vgs / ( R 0 + R 1 + R 2 + R 3 )$$

$$Vref 3 = Vdd - ( R 3 ) \cdot Vgs / ( R 0 + R 1 + R 2 + R 3 )$$

In the equations, Vgs is the gate-source voltage when transistors 221 and 222 are in equilibrium. At this time, the current of the transistor 235 can be set to make the gate-source voltage of the transistor 234 and the gate-source voltage of each of the transistors 221 and 222 equal to each other.

Then, the drain current of each of the transistors 241 and 242 is set on the basis of the current mirror operation of the transistors 243 and 244. Then, the drain potential of the transistor 242 changes according to the magnitude relationship between the detection value Vdet of the oscillation amplitude Vosc and the reference voltage Vref1. The drain potential is applied to the gate of the transistor 247, and the transistor 247 is thereby switched on and off. At this time, if Vdet>Vref1, the transistor 247 is switched on and the output voltage Vout1 reaches a high level, and if Vdet<Vref1, the transistor 247 is switched off and the output voltage Vout1 reaches a low level.

Furthermore, the drain current of each of the transistors 251 and 252 is set on the basis of the current mirror operation of the transistors 253 and 254. Then, the drain potential of the transistor 252 changes according to the magnitude relationship between the detection value Vdet of the oscillation amplitude Vosc and the reference voltage Vref2. The drain potential is applied to the gate of the transistor 257, and the transistor 257 is thereby switched on and off. At this time, if Vdet>Vref2, the transistor 257 is switched on and the output voltage Vout2 reaches a high level, and if Vdet<Vref2, the transistor 257 is switched off and the output voltage Vout2 reaches a low level.

Furthermore, the drain current of each of the transistors 261 and 262 is set on the basis of the current mirror operation of the transistors 263 and 264. Then, the drain potential of the transistor 262 changes according to the magnitude relationship between the detection value Vdet of the oscillation amplitude Vosc and the reference voltage Vref3. The drain potential is applied to the gate of the transistor 267, and the transistor 267 is thereby switched on and off. At this time, if Vdet>Vref3, the transistor 267 is switched on and the output voltage Vout3 reaches a high level, and if Vdet<Vref3, the transistor 267 is switched off and the output voltage Vout3 reaches a low level.

In this manner, in the second embodiment described above, the detection circuit 102 and the voltage comparison unit 104 of the calibration circuit 101 include field effect transistors. This enables the integration of the calibration circuit 101, so that the downsizing and cost reduction of the calibration circuit 101 can be achieved.

Note that in the above-described embodiments, it has been explained that a detection value of an oscillation amplitude is compared with three different reference voltages on the positive electrode side of the oscillation amplitude of an LC oscillator. Alternatively, the detection value of the oscillation amplitude may be compared with two or four or more different reference voltages on the positive electrode side of the oscillation amplitude of the LC oscillator. In addition, in the above-described embodiments, it has been explained that the oscillation amplitude of the LC oscillator is compared with a plurality of different reference voltages on the positive electrode side of the oscillation amplitude of the LC oscillator. Alternatively, the oscillation amplitude of the LC oscillator may be compared with a plurality of different reference voltages on the negative electrode side of the oscillation amplitude of the LC oscillator.

Furthermore, the above-described embodiments represent examples for embodying the present technology, and the matters in the embodiments and the matters specifying the invention in the claims have a correspondence relationship. Similarly, the matters specifying the invention in the claims and the matters with the same names in the embodiments of the present technology have a correspondence relationship. However, the present technology is not limited to the embodiments, and can be embodied by applying various modifications to the embodiments without departing from the gist of the present technology. In addition, the effects described in the present specification are merely examples and are not limited, and other effects may be provided.

Note that the present technology may also have the following configuration.

(1) A calibration circuit including:
a reference voltage generation unit that generates a plurality of different reference voltages;
a voltage comparison unit that compares a detection value of an oscillation amplitude detected from an oscillation signal of an LC oscillator and the plurality of different reference voltages on a same polarity side of the oscillation amplitude; and
an amplitude adjustment unit that adjusts the oscillation amplitude on a basis of a comparison result by the voltage comparison unit.

(2) The calibration circuit according to (1), in which
the same polarity side of the oscillation amplitude is a positive electrode side or a negative electrode side of the oscillation amplitude.

(3) The calibration circuit according to (1) or (2), further including a frequency adjustment unit configured to adjust an oscillation frequency of the LC oscillator.

(4) The calibration circuit according to any one of (1) to (3), further including a detection circuit that detects the detection value on the same polarity side of the oscillation amplitude of the LC oscillator on a basis of detection of the oscillation signal of the LC oscillator.

(5) The calibration circuit according to (4), in which
the detection circuit includes:
a full-wave rectifier circuit that subjects the oscillation signal of the LC oscillator to full-wave rectification; and
a smoothing circuit that smooths a waveform subjected to full-wave rectification by the full-wave rectifier circuit.

(6) The calibration circuit according to any one of (1) to (5), in which
the reference voltages include a first reference voltage, a second reference voltage greater than the first reference voltage, and a third reference voltage greater than the second reference voltage,
the amplitude adjustment unit is configured to adjust the oscillation amplitude to make the detection value of the oscillation amplitude greater than or equal to the third reference voltage on the same polarity side of the oscillation amplitude in a first amplitude calibration period,
the frequency adjustment unit is configured to adjust the oscillation frequency to make a frequency error of the LC oscillator less than or equal to an allowable value in a frequency calibration period after the first amplitude calibration period, and
the amplitude adjustment unit is configured to adjust the oscillation amplitude to make the detection value of the oscillation amplitude greater than or equal to the first reference voltage but less than the second reference voltage on the same polarity side of the oscillation amplitude in a second amplitude calibration period after the frequency calibration period.

(7) The calibration circuit according to (6), further including a state management unit configured to manage the first amplitude calibration period, the frequency calibration period, and the second amplitude calibration period.

### REFERENCE SIGNS LIST

100 LC oscillator
101 Calibration circuit
111, 112 Transistor
113 Capacitor bank
114 Inductor
115 Variable resistor
102 Detection circuit
121 Full-wave rectifier circuit
122 Smoothing circuit
103 Reference voltage generation unit
131 to 133 Resistor
134 Current source
104 Voltage comparison unit
141 to 143 Comparator
106 Amplitude calibration unit
107 Frequency divider circuit
108 Counter
109 Frequency calibration unit
110 State management unit

1. A calibration circuit comprising:
a reference voltage generation unit that generates a plurality of different reference voltages;
a voltage comparison unit that compares a detection value of an oscillation amplitude detected from an oscillation signal of an LC oscillator and the plurality of different reference voltages on a same polarity side of the oscillation amplitude; and
an amplitude adjustment unit that adjusts the oscillation amplitude on a basis of a comparison result by the voltage comparison unit.

2. The calibration circuit according to claim 1, wherein
the same polarity side of the oscillation amplitude is a positive electrode side or a negative electrode side of the oscillation amplitude.

3. The calibration circuit according to claim 1, further comprising a frequency adjustment unit that adjusts an oscillation frequency of the LC oscillator.

4. The calibration circuit according to claim 1, further comprising a detection circuit that detects the detection value on the same polarity side of the oscillation amplitude of the LC oscillator on a basis of detection of the oscillation signal of the LC oscillator.

5. The calibration circuit according to claim 4, wherein
the detection circuit comprises:
a full-wave rectifier circuit that subjects the oscillation signal of the LC oscillator to full-wave rectification; and
a smoothing circuit that smooths a waveform subjected to full-wave rectification by the full-wave rectifier circuit.

6. The calibration circuit according to claim 3, wherein
the reference voltages include a first reference voltage, a second reference voltage greater than the first reference voltage, and a third reference voltage greater than the second reference voltage,
the amplitude adjustment unit is configured to adjust the oscillation amplitude to make the detection value of the oscillation amplitude greater than or equal to the third reference voltage on the same polarity side of the oscillation amplitude in a first amplitude calibration period,
the frequency adjustment unit is configured to adjust the oscillation frequency to make a frequency error of the LC oscillator less than or equal to an allowable value in a frequency calibration period after the first amplitude calibration period, and
the amplitude adjustment unit is configured to adjust the oscillation amplitude to make the detection value of the oscillation amplitude greater than or equal to the first reference voltage but less than the second reference voltage on the same polarity side of the oscillation amplitude in a second amplitude calibration period after the frequency calibration period.

7. The calibration circuit according to claim 6, further comprising a state management unit that manages the first amplitude calibration period, the frequency calibration period, and the second amplitude calibration period.
